(19) United States
(12) Patent Application Publication
(10) Pub. No.: US 2026/0247534 A1
(43) Pub. Date: Aug. 20, 2026

(54) CIRCUIT ASSEMBLY

(71) Applicants: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(72) Inventors: Jiahui YANG, Mie (JP); Tatsuya DAIDOJI, Mie (JP)

(21) Appl. No.: 19/161,315

(22) PCT Filed: Mar. 8, 2023
(86) PCT No.: PCT/JP2023/008787

§ 371 Date: Sep. 2, 2025

(51) Int. Cl. H05K 1/14; H05K 1/02

(52) U.S. Cl. CPC H05K 1/147; H05K 1/0296; H05K 2201/10272

(57) ABSTRACT

A circuit assembly includes: bus bars constituting a current path; a flexible printed circuit board placed on the bus bar; an electronic component mounted straddling the bus bar and the flexible printed circuit board; and a fixing member having one end portion fixed to the bus bar and another end portion fixed to the flexible printed circuit board, wherein the flexible printed circuit board includes an extended path portion extending away from the bus bar and constituting a conduction path to another circuit to which the electronic component is connected, the extended path portion includes a displacement region that is not in contact with any other member and is routed in a displaceable manner, and the other end portion of the fixing member is located between the electronic component and a linkage portion that links the placement portion and the extended path portion of the flexible printed circuit board.

### TECHNICAL FIELD

The present disclosure relates to a circuit assembly.

### BACKGROUND

A circuit assembly that is disposed between two conductive paths to establish or interrupt electrical conduction is conventionally installed in a vehicle such as an electric vehicle or a hybrid vehicle. For example, Patent Document 1 discloses a circuit assembly including: a pair of bus bars that constitute a current path between a power source and a load; an interrupting unit (electronic component) including a pair of power terminals respectively connected to the pair of bus bars to establish and interrupt electrical conduction between the pair of bus bars; and a flexible printed circuit board to which a control terminal of the interrupting unit is connected and that is placed on the bus bars.

In such a circuit assembly, the interrupting unit needs to be connected to a control circuit board on which a control unit configured to output a control signal for controlling the interrupting unit is mounted. Therefore, in the circuit assembly disclosed in Patent Document 1, the flexible printed circuit board includes an extended path portion extending away from the bus bars toward the control circuit board, and a conductor pattern on the flexible printed circuit board, to which the control terminal of the interrupting unit is connected, extends to an end portion of the extended path portion to be connected to the control circuit board.

### PRIOR ART DOCUMENT

### Patent Document

Patent Document 1: JP 2016-220277 A

### SUMMARY OF THE INVENTION

### Problems to be Solved

However, although two end portions of the extended path portion of the flexible printed circuit board in its extending direction are coupled to the flexible printed circuit board and the control circuit board, an intermediate portion between the two end portions is not in contact with any other member and is routed in a displaceable manner. Accordingly, if the extended path portion is displaced due to vibrations or the like when the circuit assembly is installed in a vehicle, an external force is applied to the conductor pattern on the flexible printed circuit board and mounted portions of the electronic component mounted straddling the flexible printed circuit board and the bus bars. This may cause damage such as a fracture or crack to the conductor pattern and the mounted portions, resulting in the occurrence of a problem in the electrical connection state.

Therefore, the present disclosure discloses a circuit assembly that can suppress damage to a conductor pattern on a flexible printed circuit board and mounted portions of an electronic component due to displacement of an extended path portion of the flexible printed circuit board.

### Means to Solve the Problem

A circuit assembly according to the present disclosure includes: a bus bar that constitutes a current path; a flexible printed circuit board including a placement portion that is placed on a surface of the bus bar; an electronic component mounted straddling the bus bar and the placement portion; and a fixing member having one end portion fixed to the surface of the bus bar and another end portion fixed to a surface of the placement portion, wherein the flexible printed circuit board includes an extended path portion that is linked to the placement portion, extends away from the surface of the bus bar, and constitutes a conduction path to another circuit to which the electronic component is connected, the extended path portion includes a displacement region that is not in contact with any other member and is routed in a displaceable manner, and the other end portion of the fixing member is located between the electronic component and a linkage portion that links the placement portion and the extended path portion of the flexible printed circuit board.

### Effect of the Invention

With the circuit assembly according to the present disclosure, it is possible to suppress damage to the conductor pattern on the flexible printed circuit board and mounted portions of the electronic component due to displacement of the extended path portion of the flexible printed circuit board.

### BRIEF DESCRIPTION OF THE DRAWINGS

FIG. 1 is a perspective view showing a circuit assembly according to Embodiment 1 as viewed through a portion of a case.

FIG. 2 is a partially exploded perspective view showing a portion of the circuit assembly shown in FIG. 1 in an exploded state.

FIG. 3 is a perspective view showing a main portion of the circuit assembly shown in FIG. 1 in an enlarged scale as viewed through a control circuit board.

FIG. 4 is a plan view of the main portion of the circuit assembly shown in FIG. 3.

FIG. 5 is a perspective view showing the main portion of the circuit assembly shown in FIG. 3 in a further enlarged scale.

### DETAILED DESCRIPTION TO EXECUTE THE INVENTION

### Description of Embodiments of Present Disclosure

First, aspects of the present disclosure are listed and described.
(1) A circuit assembly according to the present disclosure includes a bus bar that constitutes a current path; a flexible printed circuit board including a placement portion that is placed on a surface of the bus bar; an electronic component mounted straddling the bus bar and the placement portion; and a fixing member having one end portion fixed to the surface of the bus bar and another end portion fixed to a surface of the placement portion, wherein the flexible printed circuit board includes an extended path portion that is linked to the placement portion, extends away from the surface of the bus bar, and constitutes a conduction path to another circuit to which the electronic component is connected, the extended path portion includes a displacement region that is not in contact with any other member and is routed in a displaceable manner, and the other end portion of the fixing member is located between the electronic component and a linkage portion that links the placement portion and the extended path portion of the flexible printed circuit board.

In the circuit assembly according to the present disclosure, the placement portion of the flexible printed circuit board is placed on the surface of the bus bar, and the electronic component is mounted straddling the bus bar and the placement portion of the flexible printed circuit board. The flexible printed circuit board includes the extended path portion that constitutes a conduction path to the other circuit to which the electronic component is connected. The extended path portion includes the displacement region that extends away from the surface of the bus bar, is not in contact with any other member, and is routed in a displaceable manner. Accordingly, when the circuit assembly is installed in a vehicle, the displacement region of the extended path portion is displaced due to vibrations or the like. The circuit assembly according to the present disclosure includes the fixing member fixed so as to bridge the bus bar and the placement portion of the flexible printed circuit board. The one end portion of the fixing member is fixed to the surface of the bus bar, and the other end portion of the fixing member is fixed to the surface of the placement portion of the flexible printed circuit board, between the electronic component and the linkage portion that links the placement portion and the extended path portion. Therefore, even if an external force (e.g., a pulling force, a compressive force, or a force that causes the placement portion to be displaced away from the bus bar) is transmitted to the placement portion side from the linkage portion between the placement portion and the extended path portion of the flexible printed circuit board due to displacement of the displacement region of the extended path portion, the other end portion of the fixing member suppresses displacement of the placement portion, and it is possible to suppress transmission of the external force to the electronic component side with respect to the other end portion. Accordingly, although the circuit assembly includes the extended path portion that is routed in a displaceable manner, it is possible to suppress damage to conductor patterns on the flexible printed circuit board and mounted portions of the electronic component mounted straddling the flexible printed circuit board and the bus bar, and to advantageously maintain the electrical connection state of the circuit assembly. In particular, the one end portion of the fixing member is fixed to the surface of the bus bar, and the other end portion is fixed to the surface of the placement portion of the flexible printed circuit board, and therefore, it is possible to realize the function of suppressing displacement of the placement portion by the other end portion of the fixing member by utilizing a force with which the fixing member is fixed to the bus bar. Therefore, it is possible to suppress, with a simple structure, damage to the conductor patterns on the flexible printed circuit board and the mounted portions of the electronic component, which would otherwise be caused by displacement of the extended path portion.

Note that the fixing member may have a suitable shape and may be made of a suitable material as long as the fixing member is fixed so as to bridge the bus bar and the placement portion of the flexible printed circuit board. Also, a suitable fixing structure can be adopted for the two end portions of the fixing member as long as the end portions can be fixed to the bus bar and the flexible printed circuit board. For example, the fixing member may be fixed with an adhesive or by welding or the like, or may be fixed in a manner that enables electrical conduction.
(2) In the circuit assembly described above in (1), it is preferable that the fixing member has electrical conductivity, the one end portion of the fixing member is fixed to the surface of the bus bar in a manner that enables electrical conduction, the other end portion of the fixing member is fixed to a first placement-portion-side conductor pattern in a manner that enables electrical conduction, the first placement-portion-side conductor pattern being exposed on the surface of the placement portion, and the first placement-portion-side conductor pattern is connected to the other circuit via a first path side conductor pattern provided on the extended path portion.

The fixing member has electrical conductivity, the one end portion of the fixing member is fixed to the bus bar in a manner that enables electrical conduction, and the other end portion is fixed to the first placement-portion-side conductor pattern on the flexible printed circuit board in a manner that enables electrical conduction, and therefore, the fixing member can also be used as an electrically conductive member. Moreover, the first placement-portion-side conductor pattern can be connected to the other circuit via the first path side conductor pattern provided on the extended path portion, and therefore, it is possible to form another current circuit with use of the fixing member without increasing the number of components. Accordingly, the fixing member can be used as a member that constitutes a current path between the bus bar and the first placement-portion-side conductor pattern, and a path for obtaining potential information regarding the bus bar. Note that, as long as the fixing member can be fixed to the bus bar and the flexible printed circuit board in a manner that enables electrical conduction, a suitable method such as soldering or welding can be adopted as the method for fixing the two end portions of the fixing member in a manner that enables electrical conduction.
(3) In the circuit assembly described above in (1) or (2), it is preferable that the fixing member is formed by bending two end portions of a band plate metal fitting into a crank shape toward one side in a plate thickness direction, one of the two end portions having the crank shape constitutes the one end portion fixed to the surface of the bus bar, and another end portion of the two end portions constitutes the other end portion fixed to the surface of the placement portion. The two end portions of the fixing member respectively fixed to the surface of the bus bar and the surface of the placement portion of the flexible printed circuit board are bent into the crank shape, and accordingly, an external force transmitted from the bus bar or the extended path portion of the flexible printed circuit board can be absorbed through deformation of the crank-shaped portions. This can improve the function of suppressing displacement of the placement portion by the fixing member. Moreover, in the case where the one end portion and the other end portion of the fixing member are respectively connected and fixed to the bus bar and the first placement-portion-side conductor pattern in a manner that enables electrical conduction, the crank-shaped one end portion and other end portion prevent solder from spreading to a center portion of the fixing member. Therefore, it is possible to prevent an unexpected occurrence of problems such as spreading of the solder, a short circuit, and the like.
(4) In the circuit assembly described above in (2), it is preferable that the bus bar includes an input side bus bar and an output side bus bar that constitute the current path between two conductive paths, the placement portion is placed on a surface of the output side bus bar, the electronic component constitutes an interrupting unit configured to establish and interrupt electrical conduction between the input side bus bar and the output side bus bar, the interrupting unit includes: an input side power terminal mounted on a surface of the input side bus bar; an output side power terminal mounted on the surface of the output side bus bar; and a control terminal mounted on a second placement-portion-side conductor pattern exposed on the surface of the placement portion, the one end portion of the fixing member is fixed to the surface of the input side bus bar in a manner that enables electrical conduction, and the second placement-portion-side conductor pattern is connected to a control circuit that is the other circuit via a second path side conductor pattern provided on the extended path portion.

The circuit assembly according to this aspect is disposed between the two conductive paths, and can control electrical conduction between the two conductive paths and interruption of the electrical conduction. The second placement-portion-side conductor pattern to which the control terminal of the interrupting unit is connected to the control circuit that is the other circuit via the second path side conductor pattern, and can receive a control signal from the control circuit via the extended path portion spaced apart from the bus bar. That is to say, the control circuit that transmits a control signal to the interrupting unit can be spaced apart from the pair of bus bars and the interrupting unit. Therefore, even if the circuit assembly is used in applications in which a large current is caused to pass through the bus bars, such as a case where the circuit assembly is disposed between a high-voltage battery and a high-voltage load, there is no need to give considerations to high voltage and large current when designing the control circuit. Moreover, the one end portion of the fixing member is fixed to the surface of the input side bus bar, on which the input side terminal of the interrupting unit is mounted, in a manner that enables electrical conduction, and is connected to the control circuit that is the other circuit via the first placement-portion-side conductor pattern, to which the other end portion of the fixing member is fixed in a manner that enables electrical conduction, and the first path side conductor pattern. Therefore, it is possible to provide the control circuit with potential information regarding the input side of the interrupting unit, for example, and to improve the control performance of the circuit assembly realized by the control circuit.

Note that, in the circuit assembly according to this aspect, it is sufficient that the first and second path side conductor patterns provided on the extended path portion of the flexible printed circuit board are connected to the control circuit, and such a configuration includes a configuration in which the control circuit is housed in a case in which the circuit assembly is housed and a configuration in which the first and second path side conductor patterns are connected directly to the control circuit disposed at a location different from the location of the circuit assembly or are connected to the control circuit via another conductive path.

### Details of Embodiments of Present Disclosure

The following describes specific examples of a circuit assembly according to the present disclosure with reference to the drawings. Note that the present disclosure is not limited to the following examples, but is defined by the claims, and is intended to encompass all modifications within the meanings and scope that are equivalent to the claims.

### Embodiment 1

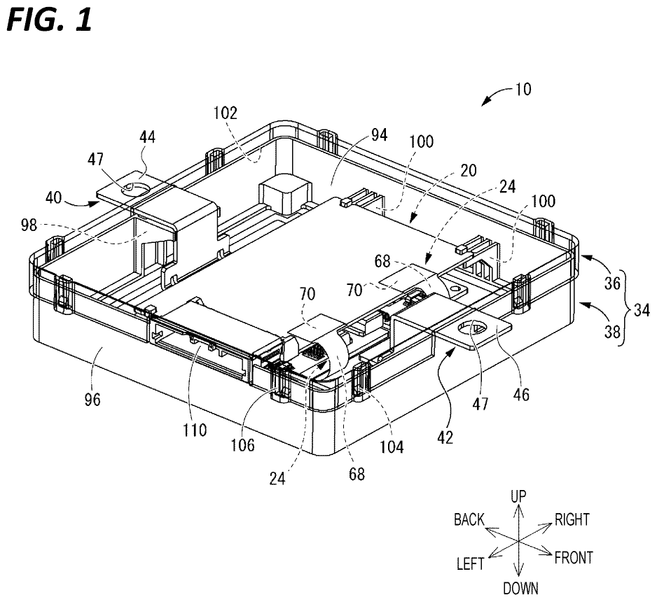

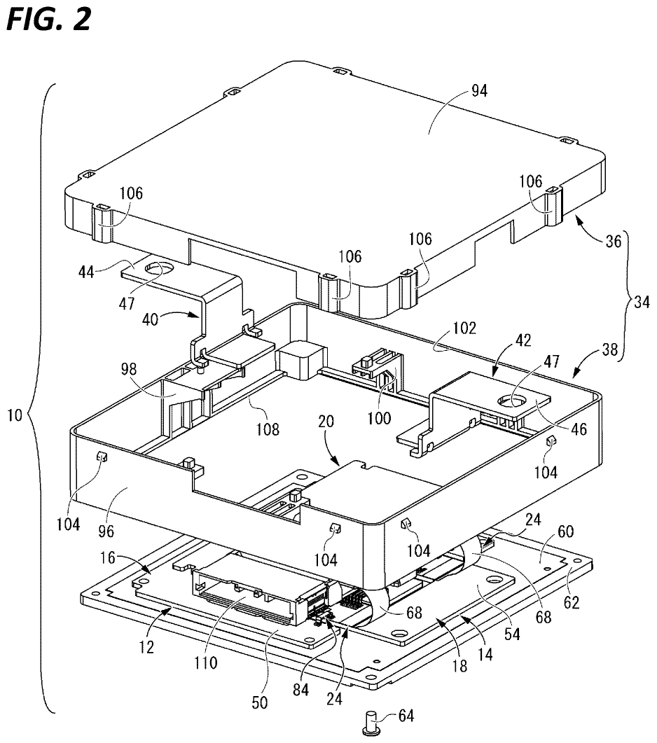

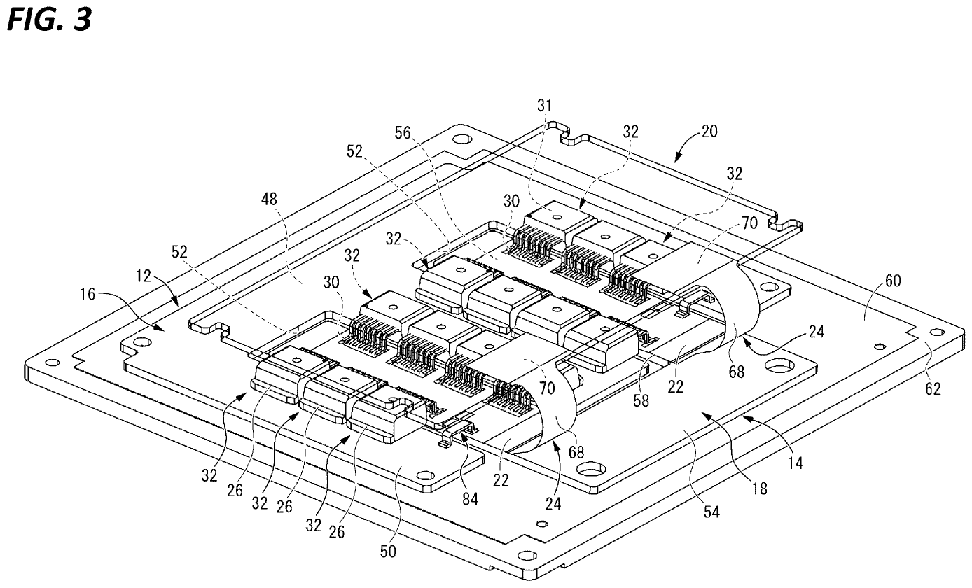

The following describes an electric connection box 10 according to Embodiment 1 of the present disclosure with reference to FIGS. 1 to 6. The electric connection box 10 is an example of a circuit assembly. The electric connection box 10 is disposed between a high-voltage battery and a high-voltage load that are two conductive paths in a vehicle such as an electric vehicle or a hybrid vehicle, for example, and establishes or interrupts electrical conduction between the high-voltage battery and the high-voltage load. Although the electric connection box 10 can be disposed in a suitable orientation, in the following description, an up-down direction, a front-rear direction, and a left-right direction respectively refer to those directions shown in FIG. 1. When there are a plurality of identical members, only some of the members may be denoted by reference signs, and reference signs may be omitted for the other members.

### Electric Connection Box 10

The electric connection box 10 includes an input side bus bar 12 and an output side bus bar 14 that constitute a current path between a power source (e.g., a high-voltage battery) that is one of two conductive paths (not shown) and a load (e.g., a high-voltage load) that is the other of the two conductive paths. The electric connection box 10 also includes: flexible printed circuit boards (hereinafter referred to as “FPCs”) 24 that include a placement portion 22 placed on a surface 18 of the output side bus bar 14; and interrupting units 32 that are electronic components mounted straddling the input side bus bar 12, the output side bus bar 14, and the placement portions 22 of the FPCs 24. The interrupting units 32 include: a drain terminal 26 that is an input side power terminal mounted on a surface 16 of the input side bus bar 12; a source terminal 28 that is an output side power terminal mounted on the surface 18 of the output side bus bar 14; and a control terminal 30 mounted on a conductor pattern (a second placement-portion-side conductor pattern 80, which will be described later) exposed on a surface 23 of the corresponding placement portion 22. The interrupting units 32 establish and interrupt electrical conduction between the input side bus bar 12 and the output side bus bar 14.

In Embodiment 1, the electric connection box includes a case 34 for housing the input side bus bar 12, the output side bus bar 14, a control circuit board 20, the FPCs 24, and the interrupting units 32. In particular, the case 34 according to Embodiment 1 includes an upper case 36 and a lower case 38. Also, in Embodiment 1, a drain side end bus bar 40 is connected to the input side bus bar 12, and a source side end bus bar 42 is connected to the output side bus bar 14. An end portion of the drain side end bus bar 40 on the side opposite to its portion connected to the input side bus bar 12 constitutes a drain side external connection portion 44 that protrudes to the outside of the case 34. Furthermore, an end portion of the source side end bus bar 42 on the side opposite to its portion connected to the output side bus bar 14 constitutes a source side external connection portion 46 that protrudes to the outside of the case 34. The drain side external connection portion 44 and the source side external connection portion 46 each have a through hole 47 extending through the connection portion in the thickness direction.

### Input Side Bus Bar 12

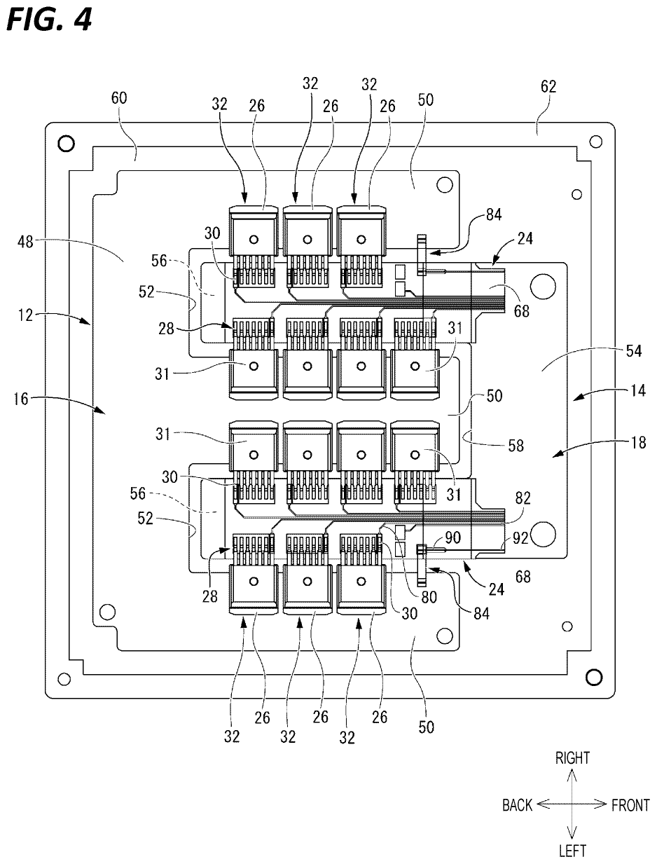

The input side bus bar 12 is a metal flat plate that is substantially E-shaped as a whole, and is formed of a metal having good electrical conductivity such as copper (including copper alloys) or aluminum (including aluminum alloys), for example. In Embodiment 1, the input side bus bar 12 is disposed such that openings in the E-shape face forward as shown in FIG. 4. That is to say, a coupling portion 48 extending in the left-right direction is provided in a rear portion of the input side bus bar 12, and drain side connection portions 50 to which the drain terminals 26 described above are connected extend forward from both end portions and a center portion of the coupling portion 48 in the left-right direction.

That is to say, the drain side connection portions 50 extending in the front-rear direction are provided at both end portions and a center portion of the input side bus bar 12 in the left-right direction, and rear end portions of the drain side connection portions 50 are coupled by the coupling portion 48. Also, front openings 52 that are open to the front are formed between the drain side connection portion 50 provided at the center portion of the input side bus bar 12 in the left-right direction and the drain side connection portions 50 provided at both end portions of the input side bus bar 12 in the left-right direction. The drain side end bus bar 40 described above is fixed to the coupling portion 48 of the input side bus bar 12 through welding, for example. The drain side external connection portion 44 of the drain side end bus bar 40 is configured to be connected to a wire, a bus bar, or the like included in the power source (not shown) with use of the through hole 47 or without the use of the through hole 47.

### Output Side Bus Bar 14

The output side bus bar 14, which is the other bus bar of the pair of bus bars, is a metal flat plate that is substantially U-shaped as a whole, and is formed of a metal having good electrical conductivity such as copper (including copper alloys) or aluminum (including aluminum alloys), for example. In Embodiment 1, the output side bus bar 14 is disposed such that the opening in the U-shape faces rearward as shown in FIG. 4. That is to say, a coupling portion 54 extending in the left-right direction is provided in a front portion of the output side bus bar 14, and source side connection portions 56 to which the source terminal 28 described above is connected extend rearward from both end portions of the coupling portion 54 in the left-right direction.

That is to say, the source side connection portions 56 extending in the front-rear direction are provided at both end portions of the output side bus bar 14 in the left-right direction, and front end portions of the source side connection portions 56 are coupled by the coupling portion 54. Also, a rear opening 58 that is open to the rear is formed at a center portion of the output side bus bar 14 in the left-right direction. The source side end bus bar 42 described above is fixed to the coupling portion 54 of the output side bus bar 14 through welding, for example. The source side external connection portion 46 of the source side end bus bar 42 is configured to be connected to a wire, a bus bar, or the like included in the load (not shown) with use of the through hole 47 or without the use of the through hole 47.

Note that the input side bus bar 12 and the output side bus bar 14 have substantially the same thickness, and the height position (position in the up-down direction) of the surface 16 of the input side bus bar 12 and the height position of the surface 18 of the output side bus bar 14 are substantially the same in the state where the input side bus bar 12 and the output side bus bar 14 are fixed on an adhesive sheet 60 and a bottom plate 62 described below.

The input side bus bar 12 and the output side bus bar 14 are bonded to the bottom plate 62 made of a metal via the adhesive sheet 60, which has a substantially rectangular shape, for example. On the adhesive sheet 60, the input side bus bar 12 and the output side bus bar 14 are arranged so as to face each other in the front-rear direction, and the output side bus bar 14 is placed on a front portion of the adhesive sheet 60 and the input side bus bar 12 is placed on a rear portion of the adhesive sheet 60. The drain side connection portion 50 at the center of the input side bus bar 12 in the left-right direction is disposed in the rear opening 58 of the output side bus bar 14. Also, the source side connection portions 56 at both end portions of the output side bus bar 14 in the left-right direction are respectively disposed in the front openings 52 of the input side bus bar 12. Thus, the drain side connection portions 50 and the source side connection portions 56 are alternately arranged in the left-right direction in an intermediate portion of the adhesive sheet 60 in the front-rear direction. The drain side connection portions 50 and the source side connection portions 56 face each other across a predetermined distance in the left-right direction.

Note that the adhesive sheet 60 preferably has insulating properties and heat conductive properties, and a conventionally-known heat conductive sheet may be adopted as the adhesive sheet, for example. As the material of the adhesive sheet 60, it is possible to use, for example, polyethylene terephthalate (PET), polyethylene naphthalate (PEN), polytetrafluoroethylene (PTFE), polycarbonate (PC), polyimide (PI), or the like. That is to say, the adhesive sheet 60 is made of a synthetic resin that has a higher thermal conductivity than air, for example. Specifically, it is possible to use a silicone resin or a non-silicone resin such as an acrylic resin or a ceramic resin. More specifically, examples of the material of the adhesive sheet include a heat-dissipation gap filler, thermally conductive grease, thermally conductive silicone rubber, and the like that are made of a silicone resin. In Embodiment 1, the adhesive sheet 60 has a sheet shape, but there is no limitation to this configuration, and any suitable shape can be adopted.

The bottom plate 62 is large enough to cover a lower opening 108 of the lower case 38, which will be described later, and is fixed to the lower case 38 with a screw 64. If the bottom plate 62 is made of a metal, it is possible to dissipate heat generated in the interrupting unit 32 and the like through, for example, a metal housing or the like (not shown) on which the electric connection box 10 is placed via the input side bus bar 12, the output side bus bar 14, the adhesive sheet 60, and the bottom plate 62. Note that if the bottom plate 62 is made of a synthetic resin, it is possible to omit the adhesive sheet 60 and fix the input side bus bar 12 and the output side bus bar 14 to the bottom plate 62 with use of a conventionally-known fixing method such as a method using bolts, for example.

### Flexible Printed Circuit Board (FPC 24)

The placement portions 22 of the FPCs 24, which are flexible printed circuit boards, are placed on the surface 18 of the output side bus bar 14. As shown in FIG. 4, conductor patterns (a first placement-portion-side conductor pattern 90 and a second placement-portion-side conductor pattern 80), which will be described later, are printed on the surface 23 of the placement portions 22 of the FPCs 24, and these conductor patterns (the first placement-portion-side conductor pattern 90 and the second placement-portion-side conductor pattern 80) are exposed on the surface 23 of the placement portion 22.

In Embodiment 1, the electric connection box includes a pair of FPCs 24 and 24, and each FPC 24 is substantially band-shaped. A portion of each FPC 24 on one end side in its length direction is placed on a corresponding source side connection portion 56 of the output side bus bar 14 and is fixed thereto through bonding or the like. In Embodiment 1, the placement portion 22 provided on the one end side in the length direction of each FPC 24 is overlaid over substantially the entire surface of the corresponding source side connection portion 56 and is fixed thereto. The placement portion 22 of each FPC 24 has substantially rectangular through holes 66 at position correspondings to the positions of the source terminals 28 of the interrupting units 32. In Embodiment 1, the electric connection box includes a plurality of interrupting units 32 as described later, and accordingly, a plurality of through holes 66 are formed in the placement portion 22 of each FPC 24 and the surface 18 of the output side bus bar 14 is partially exposed via these through holes 66.

Also, each FPC 24 includes, as an intermediate portion in its length direction, an extended path portion 68 that is linked to the placement portion 22, extends away from the surface 18 of the output side bus bar 14, and constitutes a conduction path to the control circuit board 20 that constitutes a control circuit to which the control terminals 30 of the interrupting units 32 are connected. The extended path portion 68 is curved by folding back another end portion of each FPC 24 in the length direction upward relative to the placement portion 22 placed on the corresponding source side connection portion 56. At an extended end of the extended path portion 68, each FPC 24 includes a connection portion 70 electrically connected to the control circuit (not shown) on the control circuit board 20, as the other end portion of the FPC 24 in the length direction, and the extended end side of the extended path portion 68 of each FPC 24 is electrically connected and fixed to the control circuit board 20 via the connection portion 70. A first path side conductor pattern 92 and a second path side conductor pattern 82 respectively extending from the first placement-portion-side conductor pattern 90 and the second placement-portion-side conductor pattern 80, which will be described later, to the connection portion 70 are printed on the extended path portion 68 of each FPC 24 and exposed on the surface of the extended path portion 68.

As described above, the extended path portion 68 of each FPC 24 includes a displacement region 74 that is not in contact with any other member and is routed in a displaceable manner as a region between the connection portion 70 fixed to the control circuit board 20 and a linkage portion 72 that links the extended path portion 68 and the placement portion 22 and serves as the boundary between the placement portion 22 and the extended path portion 68. Both ends of the displacement region 74 in the length direction are fixed, and the displacement region 74, which has an extra length that allows the displacement region 74 to bend, is curved without coming into contact with any other member. Therefore, when the electric connection box is installed in a vehicle, the displacement region 74 of the extended path portion 68 can be freely displaced due to vibrations or the like.

### Interrupting Unit 32

The interrupting units 32, which establish and interrupt electrical conduction between the input side bus bar 12 and the output side bus bar 14, are connected to a drain side connection portion 50 of the input side bus bar 12 and a source side connection portion 56 of the output side bus bar 14. In Embodiment 1, the interrupting units 32 are power MOSFETs (Metel-Oxide-Semiconductor Field-Effect Transistors), which are power semiconductors. Also, in Embodiment 1, the electric connection box includes a plurality of interrupting units 32 each extending between a drain side connection portion 50 and a source side connection portion 56 that face each other with a predetermined distance therebetween in the left-right direction, and the plurality of interrupting units 32 are lined up along the front-rear direction and the left-right direction.

Each interrupting unit 32 includes the drain terminal 26 as the input side power terminal, the source terminal 28 as the output side power terminal, and the control terminal 30. The drain terminal 26, the source terminal 28, and the control terminal 30 protrude outward from a body portion 31 that has a substantially rectangular block shape and constitutes the interrupting unit 32. Note that it is possible to adopt a conventionally-known power MOSFET as the interrupting units 32, and therefore, descriptions of a specific structure of the body portion 31 are omitted.

In each interrupting unit 32, the drain terminal 26 is constituted by a substantially plate-shaped terminal fitting, constitutes a large region of a bottom surface (lower surface) of the body portion 31, and protrudes outward (e.g., in each interrupting unit 32 included in the bottom row in FIG. 4, in the direction of the arrow indicating the left side) from the body portion 31.

Also, in each interrupting unit 32 of Embodiment 1, the source terminal 28 includes a plurality of terminal fittings 76. The plurality of terminal fittings 76 included in the source terminal 28 protrude outward from the body portion 31 in the direction opposite to the drain terminal 26 (e.g., in the interrupting units 32 included in the bottom row in FIG. 4, the direction of the arrow pointing to the right), and the plurality of terminal fittings 76 are arranged in parallel. For example, in FIG. 4, six terminal fittings 76 are next to one another along the direction of the arrows pointing to the front and the rear. Although there is no limitation on the shape of the terminal fittings 76, each terminal fitting 76 in Embodiment 1 is bent substantially into an L-shape and has a gull-wing shape, and includes a vertical portion 78 extending in the up-down direction as an intermediate portion thereof in the length direction. That is to say, each terminal fitting 76 protrudes outward from an intermediate portion of the body portion 31 in the up-down direction and then extends in the up-down direction in the vertical portion 78, and a protruding end portion of the terminal fitting 76 extends in the same direction as the direction in which the terminal fitting 76 protrudes from the body portion 31.

Furthermore, the control terminal 30 of each interrupting unit 32 is arranged in parallel to the terminal fittings 76 included in the source terminal 28, and in each interrupting unit 32 included in the bottom row in FIG. 4, for example, the control terminal is provided on the front side with respect to the terminal fittings 76 in the direction indicating the front side. Although there is no limitation on the shape of the control terminal 30, the control terminal 30 in Embodiment 1 has the same shape as the terminal fittings 76 included in the source terminal 28, and includes a vertical portion 78 extending in the up-down direction as an intermediate portion thereof in the length direction. Accordingly, similarly to the terminal fittings 76, the control terminal 30 protrudes outward from the intermediate portion of the body portion 31 in the up-down direction and then extends in the up-down direction in the vertical portion 78, and a protruding end portion of the control terminal extends in the same direction as the direction in which the control terminal protrudes from the body portion 31.

The drain terminals 26 of the interrupting units 32 having the shape described above are mounted on the surface 16 of the input side bus bar 12 in the drain side connection portions 50. Specifically, bottom surfaces (lower surfaces) of the drain terminals 26 are overlaid on the surface 16 of the input side bus bar 12 in the drain side connection portions 50, and are electrically connected to the surface via solder (not shown).

Also, bottom surfaces (lower surfaces) of the source terminals 28 of the interrupting units 32 are overlaid on the FPCs 24 on the source side connection portions 56 of the output side bus bar 14. The FPC 24 on each source side connection portion 56 includes the through holes 66 at positions corresponding to the source terminals 28 (the terminal fittings 76), exposing the surface 18 of the output side bus bar 14. Bottom surfaces (lower surfaces) of the terminal fittings 76 of the interrupting units 32 are overlaid on the surface 18 of the output side bus bar in the source side connection portions 56 through the through holes 66, and are electrically connected to the surface via solder (not shown).

Furthermore, the control terminal 30 of each interrupting unit 32 is overlaid on the placement portion 22 of the FPC 24 placed on the corresponding source side connection portion 56. At the position where the control terminal 30 is overlaid on the placement portion 22 of the FPC 24, the second placement-portion-side conductor pattern 80 is exposed on the surface 23 of the placement portion 22 of the FPC 24, and the control terminal 30 is electrically connected to the second placement-portion-side conductor pattern 80 via solder (not shown). Furthermore, the second placement-portion-side conductor pattern 80 is connected to the second path side conductor pattern 82 that is exposed on the surface of the extended path portion 68 of the FPC 24. With this configuration, the control terminal 30 of each interrupting unit 32 is electrically connected to the control circuit (not shown) on the control circuit board 20 via the second placement-portion-side conductor pattern 80 and the second path side conductor pattern 82, and a control signal from the control circuit can be transmitted to each interrupting unit 32 via the control terminal 30. As described above, the control circuit board 20 including the control circuit for transmitting a control signal to the interrupting units 32 can be spaced apart from the input side bus bar 12, the output side bus bar 14, and the interrupting units 32 by using the extended path portion 68 of the FPCs 24, which is spaced apart from the input side bus bar 12 and the output side bus bar 14. Therefore, even if a large current is caused to pass through the input side bus bar 12 and the output side bus bar 14 of the electric connection box 10, there is no need to give considerations to high voltage and large current when designing the control circuit, and the degree of freedom of design of the control circuit can be increased.

Note that other conductor patterns that are electrically connected to the control circuit board 20 may also be provided as necessary on the placement portion 22 and the extended path portion 68 of each FPC 24, although detailed descriptions thereof are omitted.

### Fixing Member 84

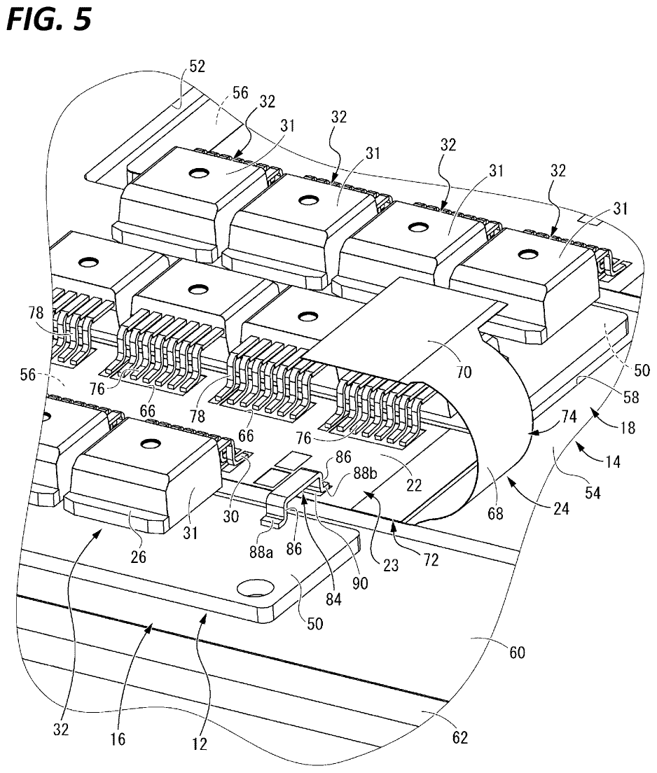

As shown in an enlarged scale in FIG. 5, the electric connection box 10 according to the present embodiment further includes a fixing member 84 having one end portion fixed to the surface 16 of the input side bus bar 12 and another end portion fixed to the surface 23 of the placement portion 22 of the FPC 24. The fixing member 84 is constituted by a band plate metal fitting made of copper (including copper alloys) or aluminum (including aluminum alloys) having good electrical conductivity, for example, and two end portions of the band plate metal fitting are bent into a crank shape toward one side in the plate thickness direction to substantially form a gate shape. Specifically, the two end portions of the band plate metal fitting are bent substantially at a right angle toward the same side in the plate thickness direction to form leg portions 86 on both sides in the longitudinal direction. Respective leading end portions of the leg portions 86 are bent substantially at a right angle so as to protrude away from each other, forming a pair of fixing portions 88a and 88b at the two end portions of the fixing member 84. That is to say, one of the two end portions bent into the crank shape constitutes the fixing portion 88a, and the other end portion constitutes the other fixing portion 88b.

The fixing portion 88a, which is the one end portion of the fixing member 84, is fixed to the surface 16 of the input side bus bar 12 by soldering, welding, or the like, for example, to establish electrical conduction. The fixing portion 88b, which is the other end portion of the fixing member 84, is fixed to the first placement-portion-side conductor pattern 90 exposed on the surface 23 of the placement portion 22 of the FPC 24 via solder (not shown) to establish electrical conduction. The first placement-portion-side conductor pattern 90 is connected to the first path side conductor pattern 92 exposed on the surface of the extended path portion 68 of the FPC 24. With this configuration, it is possible to provide the control circuit on the control circuit board 20 with potential information regarding the input side bus bar 12 on which the drain terminals 26 of the interrupting units 32 are mounted and to which the fixing portion 88a of the fixing member 84 is fixed in a manner that enables electrical conduction, via the first placement-portion-side conductor pattern 90, to which the fixing portion 88b of the fixing member 84 is fixed in a manner that enables electrical conduction, and the first path side conductor pattern 92. As a result, it is possible to improve the control performance of the electric connection box 10 realized by the control circuit. Here, the position of the fixing member 84 is set such that the fixing portion 88b, which is the other end portion of the fixing member 84, is located between the linkage portion 72 between the placement portion 22 and the extended path portion 68 of the FPC 24 and an interrupting unit 32 that is an electronic component adjacent to the linkage portion 72. If the fixing member 84 is provided at this position, the fixing member 84 can advantageously suppress or prevent the occurrence of a situation in which displacement of the extended path portion 68 due to vibrations, which will be described later, is transmitted to the placement portion 22.

### Case 34

Although there is no limitation on the specific shape of the case 34, the case 34 in Embodiment 1 has a substantially rectangular box shape as a whole, and the case 34 includes the upper case 36 and the lower case 38 as described above. The case 34 (the upper case 36 and the lower case 38) can be formed of a synthetic resin, for example.

The upper case 36 has a substantially flat plate shape or a box shape that is open downward, and includes a top wall 94 that has a substantially rectangular shape as a whole. The lower case 38 has a substantially rectangular tube shape and includes a peripheral wall 96 that has a ring shape as a whole. Bus bar support portions 98 are provided on an inner peripheral surface of the peripheral wall 96 on both sides in the front-rear direction. The portions of the drain side end bus bar 40 and the source side end bus bar 42 extending outward are respectively placed on the bus bar support portions 98, and the drain side external connection portion 44 and the source side external connection portion 46 protrude outward from the case 34 in the front-rear direction.

Furthermore, circuit board support portions 100 are provided on the inner peripheral surface of the peripheral wall 96 on both sides in the left-right direction. The circuit board support portions 100 are provided at two positions spaced apart from each other in the front-rear direction on each of the left side and the right side, and the control circuit board 20 connected to the connection portions 70 provided at respective end portions of the FPCs 24 located above the extended path portions 68 is placed on the circuit board support portions 100 and supported at four positions on its outer peripheral edge. Thus, the control circuit board 20 is kept from coming into contact with the interrupting units 32 located below, and is spaced apart from the interrupting units 32 above the interrupting units 32.

An upper opening 102 of the lower case 38 is covered by the upper case 36, and the peripheral wall 96 of the lower case 38 and the upper case 36 are fixed using an appropriate method. In the present embodiment, hooks 104 protruding from an outer surface of the peripheral wall 96 at a plurality of positions spaced apart from each other in the circumferential direction are fitted to lock portions 106 provided in the upper case 36 at a plurality of positions spaced apart from each other in the circumferential direction to fix the upper case 36 to the lower case 38. Also, the bottom plate 62 to which the drain side bus bar 12, the output side bus bar 14, the FPCs 24, the interrupting units 32, and the like have been attached is placed over the lower opening 108 of the lower case 38 and fixed with the screws 64 as described above. The case 34 is configured as described above.

### Assembly Process of Electric Connection Box 10

Next, the following describes a specific example of a process for assembling the electric connection box 10. Note that the process for assembling the electric connection box 10 is not limited by the following description.

First, the drain side bus bar 12 and the output side bus bar 14 are bonded to the bottom plate 62 via the adhesive sheet 60. Thereafter, the FPCs 24 having the through holes 66 are overlaid on the source side connection portions 56 of the output side bus bar 14 and fixed thereto with an adhesive or the like, for example. Then, the interrupting units 32 are disposed so as to extend between the drain side connection portions 50 of the input side bus bar 12 and the source side connection portions 56 of the output side bus bar 14 (i.e., on the FPCs 24 placed thereon). Thus, the drain terminal 26 of each interrupting unit 32 is overlaid on the corresponding drain side connection portion 50. The terminal fittings 76 included in the source terminals 28 of the interrupting units 32 are overlaid on the surface 18 of the corresponding source side connection portion 56 via the corresponding through holes 66 in the FPC 24. Furthermore, the control terminal 30 of each interrupting unit 32 is overlaid on the second placement-portion-side conductor pattern 80 exposed on the surface 23 of the placement portion 22 of the FPC 24.

Subsequently, the fixing member 84 is disposed at the above-described position, and the fixing portion 88a of the fixing member 84 is overlaid on the surface 16 of the drain side connection portion 50 of the input side bus bar 12 located below in FIG. 5. The fixing portion 88b of the fixing member 84 is overlaid on the first placement-portion-side conductor pattern 90 on the placement portion 22 of the FPC 24. Thus, the fixing portion 88b of the fixing member 84 is overlaid on the surface of the first placement-portion-side conductor pattern 90 at a position between the linkage portion 72 between the placement portion 22 and the extended path portion 68 of the FPC 24 and the interrupting unit 32 that is the electronic component closest to the linkage portion 72.

Then, the overlaid portions described above, i.e., each drain terminal 26 and the corresponding drain side connection portion 50 (the input side bus bar 12), the terminal fittings 76 included in each source terminal 28 and the corresponding source side connection portion 56 (the output side bus bar 14), the control terminals 30 and the second placement-portion-side conductor pattern 80, the fixing portion 88a of the fixing member 84 and the drain side connection portion 50 (the input side bus bar 12) located below, and the fixing portion 88b of the fixing member 84 and the first placement-portion-side conductor pattern 90 are electrically connected to each other through soldering. Note that a conventionally-known soldering method such as reflow soldering can be adopted, for example.

Thereafter, the bottom plate 62 to which the input side bus bar 12, the output side bus bar 14, the FPCs 24, the interrupting units 32, and the fixing member 84 have been attached as described above is fixed with the screws 64 so as to cover the lower opening 108 of the lower case 38. Next, the drain side end bus bar 40 and the source side end bus bar 42 are inserted from the upper opening 102 of the lower case 38 and respectively placed on the bus bar support portions 98. Also, the lower ends of the drain side end bus bar 40 and the source side end bus bar 42 are respectively fixed to the coupling portion 48 of the drain side bus bar 12 and the coupling portion 54 of the output side bus bar 14.

Subsequently, the extended path portion 68 of the FPCs 24 is folded back upward, the connection portions 70 provided at the ends of the folded-back extended path portions 68 are fixed to the control circuit board 20 in a manner that enables electrical conduction, and the first path side conductor pattern 92 and the second path side conductor pattern 82 on the FPCs 24 are electrically connected to the control circuit on the control circuit board 20. Then, the control circuit board 20 is placed on the circuit board support portions 100 of the lower case 38. Lastly, the upper opening 102 of the lower case 38 is covered with the upper case 36, and the upper case 36 and the lower case 38 are fixed by fitting the hooks 104 to the lock portions 106 to complete the electric connection box 10.

A connector 110 provided on the control circuit board 20 in the electric connection box 10 assembled as described above is connected to an external device, for example, and when a current path interruption signal is transmitted from the outside, the interruption signal is transmitted to the control terminal 30 of each interrupting unit 32 via the control circuit on the control circuit board 20 and the second path side conductor pattern 82 and the second placement-portion-side conductor pattern 80 on each FPC 24. Then, as a result of an interruption voltage based on the interruption signal being applied to the control terminal 30, the current path is interrupted by each interrupting unit 32 to cut off the electrical connection between the input side bus bar 12 and the output side bus bar 14. Note that a microcomputer or the like that outputs the interruption signal may be mounted on the control circuit board 20, and the interruption signal may be output by the microcomputer to be transmitted to each interrupting unit 32 in response to an interruption command that is input from the outside via the connector 110.

In the electric connection box 10 according to Embodiment 1, the placement portions of the FPCs 24 are placed on the surface 18 of the output side bus bar 14, and the interrupting units 32, which are electronic components, are mounted straddling the input side bus bar 12, the output side bus bar 14, and the placement portions of the FPCs 24. Each FPC 24 includes an extended path portion 68 that constitutes a conduction path to the control circuit board 20 on which the control circuit connected to the interrupting units 32 is formed. The extended path portion 68 includes the displacement region 74 that is spaced apart from the surface 18 of the output side bus bar 14, is not in contact with any other member, and is routed in a displaceable manner, as a region between the connection portion 70 fixed to the control circuit board 20 and the linkage portion 72 that links the extended path portion 68 and the placement portion 22. When the electric connection box is installed in a vehicle, the displacement region 74 may be displaced due to vibrations or the like. However, the electric connection box 10 according to Embodiment 1 includes the fixing member 84 that is constituted by an electrically conductive member. The fixing portion 88a, which is one end portion of the fixing member 84, is fixed to the surface 16 of the input side bus bar 12 in a manner that enables electrical conduction. The fixing portion 88b, which is the other end portion of the fixing member 84, is located between the linkage portion 72, which is the boundary between the placement portion 22 and the extended path portion 68, and the interrupting unit 32 adjacent to the linkage portion 72, and is fixed to the second placement-portion-side conductor pattern 80 exposed on the surface 23 of the placement portion 22 in a manner that enables electrical conduction.

Therefore, even if the displacement region 74 of the extended path portion 68 is displaced due to vibrations of the displacement region 74, for example, and an external force (e.g., a pulling force, a compressive force, or a force that causes the placement portion 22 of the FPC 24 to be displaced away from the surface 18 of the output side bus bar 14) is transmitted to the placement portion 22 side from the linkage portion 72 between the placement portion 22 and the extended path portion 68 of the FPC 24, the fixing portion 88b of the fixing member 84 suppresses displacement on the placement portion 22 side. Thus, it is possible to suppress transmission of the external force to the interrupting unit 32 side with respect to the fixing portion 88b of the fixing member 84. Accordingly, although the extended path portion 68 includes the displacement region 74 routed in the displaceable manner, it is possible to suppress damage or the like to conductor patterns including the first placement-portion-side conductor pattern 90 and the second placement-portion-side conductor pattern 80 on the FPC 24 and mounted portions of the interrupting units 32 mounted straddling the FPC 24, the input side bus bar 12, and the output side bus bar 14. As a result, it is possible to advantageously maintain the electrical connection state of the electric connection box 10. In particular, the fixing portion 88a of the fixing member 84 is fixed to the surface 16 of the input side bus bar 12 in a manner that enables electrical conduction, and the other fixing portion 88b is fixed to the second placement-portion-side conductor pattern 80 exposed on the surface 23 of the placement portion 22 of the FPC 24 in a manner that enables electrical conduction, and therefore, it is possible to realize the function of suppressing displacement of the placement portion 22 by the other fixing portion 88b of the fixing member 84 by utilizing a force with which the fixing member 84 is fixed to the input side bus bar 12. As a result, it is possible to suppress, with a simple structure, damage to the conductor patterns on the FPC 24 and the mounted portions of the interrupting units 32, which would otherwise be caused by displacement of the displacement region 74 of the extended path portion 68.

Moreover, in the electric connection box 10 according to Embodiment 1, the fixing member 84 has electrical conductivity, and is used as an electrically conductive member connecting the input side bus bar 12 and the first placement-portion-side conductor pattern 90 in a manner that enables electrical conduction. The first placement-portion-side conductor pattern 90 is connected to the control circuit on the control circuit board 20 via the first path side conductor pattern 92 provided on the extended path portion 68, and therefore, it is possible to form another current circuit with use of the fixing member 84 without increasing the number of components. In Embodiment 1, the fixing member 84 is used as a path for obtaining potential information regarding the input side bus bar 12.

Additionally, the fixing member 84 is formed by bending two end portions of a band plate metal fitting into a crank shape toward one side in the plate thickness direction, and the fixing member 84 is substantially gate-shaped as a whole including the fixing portion 88a and the other fixing portion 88b that are bent into the crank shape. Therefore, an external force transmitted from the input side bus bar 12 or the extended path portion 68 of the FPC 24 can be absorbed through deformation of the crank-shaped fixing portions 88a and 88b. This can improve the function of suppressing displacement of the placement portion 22 by the fixing member 84. In particular, in Embodiment 1, the fixing portions 88a and 88b of the fixing member 84 are fixed with solder, and the crank-shaped fixing portions 88a and 88b prevent the solder from spreading to a center portion of the fixing member 84. Therefore, it is possible to prevent an unexpected occurrence of problems such as spreading of the solder, short circuits, and the like.

In embodiment 1, the electric connection box includes the input side bus bar 12 and the output side bus bar 14 as bus bars constituting a current path, and the fixing portion 88a, which is one end portion of the fixing member 84, is fixed to the surface 16 of the input side bus bar 12 in a manner that enables electrical conduction. Also, the fixing portion 88b, which is the other end portion of the fixing member 84, is fixed to the first placement-portion-side conductor pattern 90 in a manner that enables electrical conduction, and the first placement-portion-side conductor pattern 90 is connected to the control circuit, which is another circuit, via the first path side conductor pattern 92. Furthermore, the interrupting units 32 that establish and interrupt electrical conduction between the input side bus bar 12 and the output side bus bar 14 are adopted as electronic components, and the input side power terminals (the drain terminals 26) of the interrupting units 32 are mounted on the input side bus bar 12, and the output side power terminals (the source terminals 28) of the interrupting units 32 are mounted on the output side bus bar 14. The control terminal 30 is mounted on the second placement-portion-side conductor pattern 80, and the second placement-portion-side conductor pattern 80 is connected to the control circuit via the second path side conductor pattern 82. By adopting this configuration, it is possible to provide, for example, potential information regarding the input side of the interrupting units 32 to the control circuit, and improve the control performance of the circuit assembly (the electric connection box 10) realized by the control circuit.

### Variations

Although Embodiment 1 is described in detail as a specific example of the present disclosure, the present disclosure is not limited by the specific description. The present disclosure encompasses alterations, modifications, and the like that fall within a scope in which the object of the present disclosure can be achieved. For example, the following variations of the embodiment are also included in the technical scope of the present disclosure.
(1) In Embodiment 1, the fixing member 84 is used as an electrically conductive member connecting the input side bus bar 12 and the first placement-portion-side conductor pattern 90 in a manner that enables electrical conduction, but there is no limitation to this configuration. For example, a configuration is also possible in which the fixing member 84 has insulating properties, and is fixed with an adhesive or the like to the bus bar and the placement portion of the flexible printed circuit board to curb displacement of the placement portion.
(2) Electronic components adopted for the circuit assembly according to the present disclosure are not limited to the interrupting units 32 described as an example, and may be any electronic components mounted straddling the bus bars and the placement portion of the flexible printed circuit board.
(3) In the electric connection box 10 according to Embodiment 1, the control circuit board 20 constituting another circuit to which the extended path portion 68 of each FPC 24 is connected is housed in the same case as the case in which the extended path portion 68 is housed, but the other circuit to which the extended path portion 68 is connected need not be housed in the same case. In the circuit assembly according to the present disclosure, it is sufficient that the extended path portion 68 is connected to the other circuit, and such a configuration includes, for example, a configuration in which the extended path portion 68 is connected via a wire harness to a control circuit board that is outside the electric connection box 10.
(4) The fixing member 84 may have a suitable shape as long as the fixing member 84 can be fixed so as to bridge the bus bar and the placement portion of the flexible printed circuit board, and there is no limitation to the shape described as an example. The fixing member 84 may also have a straight plate shape, or a curved shape such as an arc shape or an ohm shape.
(5) A suitable fixing structure can be adopted for the two end portions of the fixing member as long as the end portions can be fixed to the bus bar and the flexible printed circuit board. For example, in the case where the fixing member is used as an electrically conductive member, there is no limitation to soldering described as an example, and the fixing member may also be fixed with a method that enables electrical conduction, such as welding. If the fixing member does not have electrical conductivity, it is possible to adopt a fixing structure suitable for the material of the fixing member. For example, the fixing member may be bonded with an adhesive.
(6) The shapes of the drain terminal 26, the source terminal 28, and the control terminal 30 of each interrupting unit 32, the numbers of these terminals, and the directions in which these terminals protrude from the body portion 31 are not limited to those described as examples, and it is possible to adopt suitable shapes, suitable numbers, and suitable protruding directions.

### LIST OF REFERENCE NUMERALS

10 Electric connection box (circuit assembly)
12 Input side bus bar
14 Output side bus bar
16 Surface (input side bus bar)
18 Surface (output side bus bar)
20 Control circuit board (control circuit)
22 Placement portion
23 Surface (placement portion)
24 FPC (flexible printed circuit board)
26 Drain terminal (input side power terminal)
28 Source terminal (output side power terminal)
30 Control terminal
31 Body portion (interrupting unit)
32 Interrupting unit
34 Case
36 Upper case
38 Lower case
40 Drain side end bus bar
42 Source side end bus bar
44 Drain side external connection portion
46 Source side external connection portion
47 Through hole
48 Coupling portion
50 Drain side connection portion
52 Front opening
54 Coupling portion
56 Source side connection portion
58 Rear opening
60 Adhesive sheet
62 Bottom plate
64 Screw
66 Through hole
68 Extended path portion
70 Connection portion
72 Linkage portion
74 Displacement region
76 Terminal fitting
78 Vertical portion
80 Second placement-portion-side conductor pattern
82 Second path side conductor pattern
84 Fixing member
86 Leg portion
88a, 88b Fixing portion
90 First placement-portion-side conductor pattern
92 First path side conductor pattern
94 Top wall
96 Peripheral wall
98 Bus bar support portion
100 Circuit board support portion
102 Upper opening
104 Hook
106 Lock portion
108 Lower opening
110 Connector

1. A circuit assembly comprising:
a bus bar that constitutes a current path;
a flexible printed circuit board including a placement portion that is placed on a surface of the bus bar;
an electronic component mounted straddling the bus bar and the placement portion; and
a fixing member having one end portion fixed to the surface of the bus bar and another end portion fixed to a surface of the placement portion,
wherein the flexible printed circuit board includes an extended path portion that is linked to the placement portion, extends away from the surface of the bus bar, and constitutes a conduction path to another circuit to which the electronic component is connected,
the extended path portion includes a displacement region that is not in contact with any other member and is routed in a displaceable manner, and
the other end portion of the fixing member is located between the electronic component and a linkage portion that links the placement portion and the extended path portion of the flexible printed circuit board.

212. The circuit assembly according to claim 1,
wherein the fixing member has electrical conductivity,
the one end portion of the fixing member is fixed to the surface of the bus bar in a manner that enables electrical conduction,
the other end portion of the fixing member is fixed to a first placement-portion-side conductor pattern in a manner that enables electrical conduction, the first placement-portion-side conductor pattern being exposed on the surface of the placement portion, and
the first placement-portion-side conductor pattern is connected to the other circuit via a first path side conductor pattern provided on the extended path portion.

3. The circuit assembly according to claim 1,
wherein the fixing member is formed by bending two end portions of a band plate metal fitting into a crank shape toward one side in a plate thickness direction,
one of the two end portions having the crank shape constitutes the one end portion fixed to the surface of the bus bar, and
another end portion of the two end portions constitutes the other end portion fixed to the surface of the placement portion.

4. The circuit assembly according to claim 2,
wherein the bus bar includes an input side bus bar and an output side bus bar that constitute the current path between two conductive paths,
the placement portion is placed on a surface of the output side bus bar,
the electronic component constitutes an interrupting unit configured to establish and interrupt electrical conduction between the input side bus bar and the output side bus bar,
the interrupting unit includes: an input side power terminal mounted on a surface of the input side bus bar; an output side power terminal mounted on the surface of the output side bus bar; and a control terminal mounted on a second placement-portion-side conductor pattern exposed on the surface of the placement portion,
the one end portion of the fixing member is fixed to the surface of the input side bus bar in a manner that enables electrical conduction, and
the second placement-portion-side conductor pattern is connected to a control circuit that is the other circuit via a second path side conductor pattern provided on the extended path portion.
